(19) United States
(12) Patent Application Publication
(10) Pub. No.: US 2026/0129873 A1
(43) Pub. Date: May 7, 2026

(54) SEMICONDUCTOR DEVICE

(71) Applicant: Samsung Electronics Co., Ltd., Suwon-si (KR)

(72) Inventors: Eunhye LEE, Suwon-si (KR); KEUNYOUNG LEE, Suwon-si (KR); IN-JAE LEE, Suwon-si (KR)

(21) Appl. No.: 19/214,317

(22) Filed: May 21, 2025

(30) Foreign Application Priority Data
Nov. 6, 2024 (KR) 10-2024-0156389

(51) Int. Cl. H01L 23/00; H10B 80/00

(52) U.S. Cl. CPC H10B 80/00; H10W 72/944; H10W 80/743; H10W 90/792

(57) ABSTRACT

A semiconductor device is disclosed. The semiconductor device may include a package substrate, a plurality of semiconductor chips stacked on the package substrate, each of the semiconductor chips having a first side surface, and a first conductive film, which is electrically connected to the package substrate and is extended to a region on the first side surfaces of the semiconductor chips. Each of the semiconductor chips may include a peripheral circuit structure including first bonding pads on a first surface of a substrate, a first cell array structure including a first stack and second bonding pads bonded to the first bonding pads, and a first input/output pad disposed on the first side surface and electrically connected to the first conductive film.

### CROSS-REFERENCE TO RELATED APPLICATIONS

This U.S. non-provisional patent application claims priority under 35 U.S.C. § 119 to Korean Patent Application No. 10-2024-0156389, filed on Nov. 6, 2024, in the Korean Intellectual Property Office, the entire contents of which are hereby incorporated by reference.

### BACKGROUND OF THE INVENTION

The present disclosure relates to a semiconductor device and a semiconductor package including the same.

A semiconductor device capable of storing a large amount of data is required as a data storage of an electronic system. Accordingly, many studies are being conducted to increase the data storage capacity of the semiconductor device. For example, semiconductor devices, in which memory cells are three-dimensionally arranged, are being suggested.

Furthermore, a semiconductor packaging technology of integrating a semiconductor device including memory cells in a single package is required. In the case of a semiconductor package in which multiple devices are integrated, there is a need to reduce the size of the semiconductor package and improve the heat-emission and electrical characteristics of the semiconductor package.

### SUMMARY

An embodiment of the inventive concept provides a semiconductor device with an increased integration density.

According to an embodiment of the inventive concept, a semiconductor device may include a package substrate, a plurality of semiconductor chips stacked on the package substrate, each of the semiconductor chips having a first side surface, and a first conductive film, which is electrically connected to the package substrate and is extended to a region on the first side surfaces of the semiconductor chips. Each of the semiconductor chips may include a peripheral circuit structure including first bonding pads on a first surface of a substrate, a first cell array structure including a first stack and second bonding pads bonded to the first bonding pads, and a first input/output pad disposed on the first side surface and electrically connected to the first conductive film.

According to an embodiment of the inventive concept, a semiconductor device may include a package substrate, a plurality of semiconductor chips stacked on the package substrate, each of the semiconductor chips having a first side surface, a mold layer provided on the package substrate to enclose the semiconductor chips, and a first conductive film electrically connected to the package substrate and extended to a region on the first side surfaces of the semiconductor chips. Each of the semiconductor chips may include a peripheral circuit structure including first bonding pads on a first surface of a substrate and second bonding pads on a second surface opposite to the first surface, a first cell array structure including third bonding pads bonded to the first bonding pads, and a first input/output pad, which is disposed on the first side surface and is electrically connected to the first conductive film. The first cell array structure may include a first stack including first insulating patterns and first gate patterns, which are vertically and alternately stacked, vertical structures penetrating the first stack, and bit lines electrically connected to the vertical structures.

According to an embodiment of the inventive concept, a semiconductor device may include a peripheral circuit structure including first bonding pads on a first surface of a substrate and second bonding pads on a second surface of the substrate, and a first cell array structure opposite to the first surface, a second cell array structure opposite to the second surface, a first input/output pad on a first side surface of the peripheral circuit structure, and a second input/output pad on a second side surface of the peripheral circuit structure. The first cell array structure may include a first stack including first insulating patterns and first gate patterns, which are vertically and alternately stacked, first vertical structures penetrating the first stack, and third bonding pads bonded to the first bonding pads. The second cell array structure may include a second stack including second insulating patterns and second gate patterns, which are vertically and alternately stacked, second vertical structures penetrating the second stack, and fourth bonding pads bonded to the second bonding pads.

### BRIEF DESCRIPTION OF THE DRAWINGS

FIG. 1 is a diagram schematically illustrating an electronic system including a semiconductor device according to an example embodiment of the inventive concept.

FIG. 2A is a plan view illustrating a semiconductor device according to an example embodiment of the inventive concept.

FIG. 2B is a sectional view taken along a line A-A′ of FIG. 2A to illustrate a semiconductor device according to an example embodiment of the inventive concept.

FIG. 3A is a plan view illustrating a semiconductor device according to an example embodiment of the inventive concept.

FIG. 3B is a sectional view taken along a line B-B′ of FIG. 3A to illustrate a semiconductor device according to an example embodiment of the inventive concept.

FIG. 4 is a sectional view illustrating a semiconductor device according to an example embodiment of the inventive concept.

FIG. 5 is an enlarged sectional view illustrating a portion ‘A’ of FIG. 4.

FIG. 6 is an enlarged sectional view illustrating a portion ‘P1’ of FIG. 5.

FIG. 7 is an enlarged sectional view illustrating a portion ‘P2’ of FIG. 5.

FIG. 8 is a sectional view illustrating a semiconductor package according to an example embodiment of the inventive concept.

FIG. 9 is a sectional view illustrating a semiconductor package according to an example embodiment of the inventive concept.

FIGS. 10 to 16 are sectional views illustrating a method of fabricating a semiconductor device according to an example embodiment of the inventive concept.

### DETAILED DESCRIPTION

Example embodiments of the inventive concepts will now be described more fully with reference to the accompanying drawings, in which example embodiments are shown. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

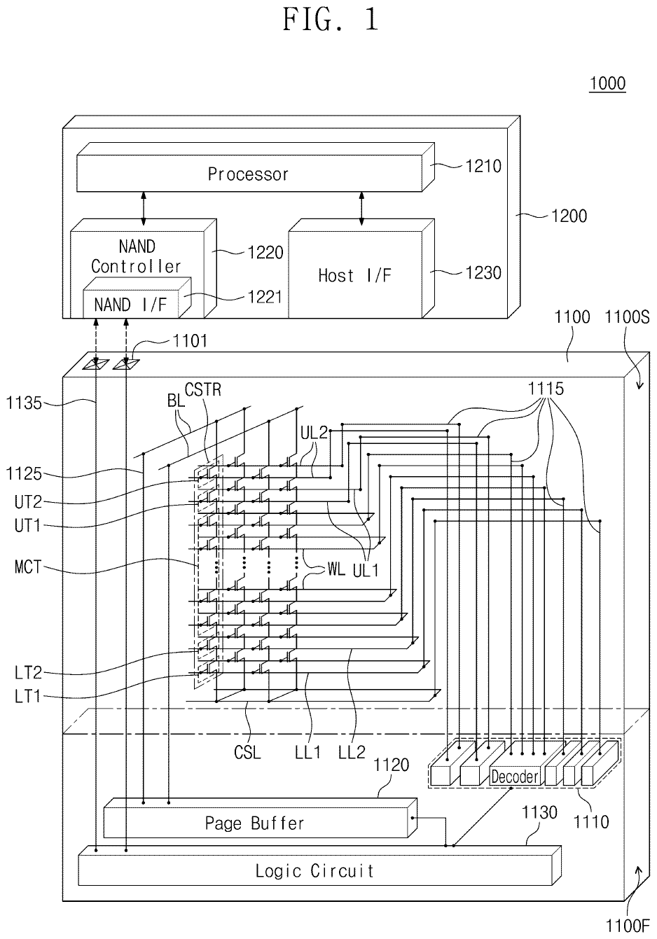

FIG. 1 is a diagram schematically illustrating an electronic system including a semiconductor device, according to an example embodiment of the inventive concept.

Referring to FIG. 1, an electronic system 1000 may include a semiconductor device 1100 and a controller 1200 electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed near the second structure 1100S.

The first structure 1100F may be a peripheral circuit structure, which includes a decoder circuit 1110, a page buffer 1120, and a logic circuit 1130. The second structure 1100S may be a memory cell structure, which includes bit lines BL, common source lines CSL, word lines WL, first and second gate upper lines UL1 and UL2, first and second gate lower lines LL1 and LL2, and memory cell strings CSTR between the bit lines BL and the common source lines CSL.

In the second structure 1100S, each of the memory cell strings CSTR may include lower transistors LT1 and LT2 adjacent to the common source line CSL, an upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be used as gate electrodes of the lower transistors LT1 and LT2, respectively. The word lines WL may be used as gate electrodes of the memory cell transistors MCT, and the gate upper lines UL1 and UL2 may be used as gate electrodes of the upper transistors UT1 and UT2, respectively.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

Although not shown in the drawings, the first structure 1100F may include a voltage generator (not shown). The voltage generator may be configured to generate a program voltage, a read voltage, a pass voltage, and a verify voltage, which are required to operate the memory cell strings CSTR. Here, the program voltage may be a relatively high voltage (e.g., 20 V to 40 V), compared with the read voltage, the pass voltage, and the verify voltage.

In an embodiment, the first structure 1100F may include high voltage transistors and low voltage transistors. The decoder circuit 1110 may include pass transistors that are connected to the word lines WL of the memory cell strings CSTR. The pass transistors may include high-voltage transistors which can stand a high voltage (e.g., the program voltage applied to the word lines WL during a programming operation). The page buffer 1120 may also include high-voltage transistors which can stand the high voltage.

The controller 1200 may include a processor 1210, a NAND controller 1220, and a host interface 1230. In an embodiment, the electronic system 1000 may include a plurality of semiconductor devices 1100, and in this case, the controller 1200 may control a plurality of semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. When a control command is received from an external host through the host interface 1230, the processor 1210 may control the semiconductor device 1100 in response to the control command.

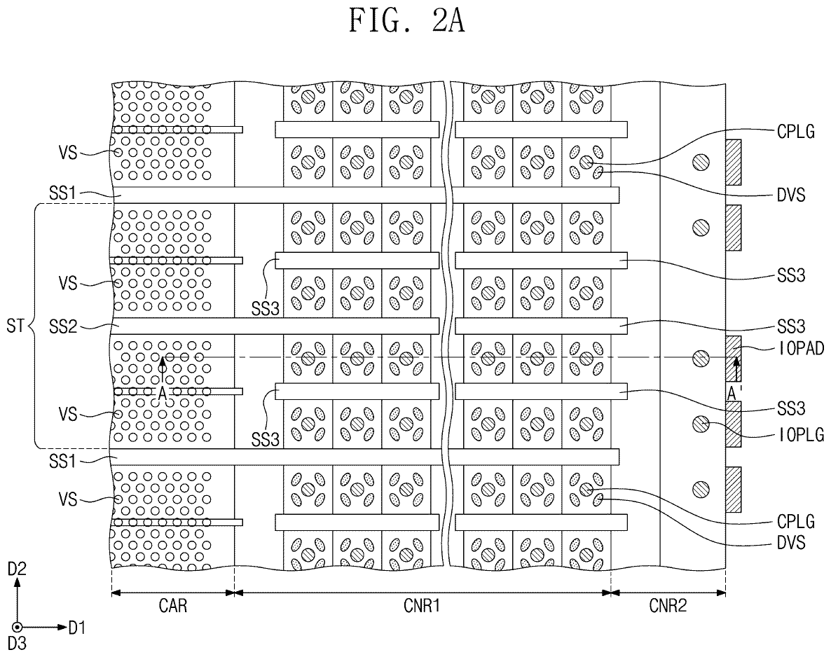

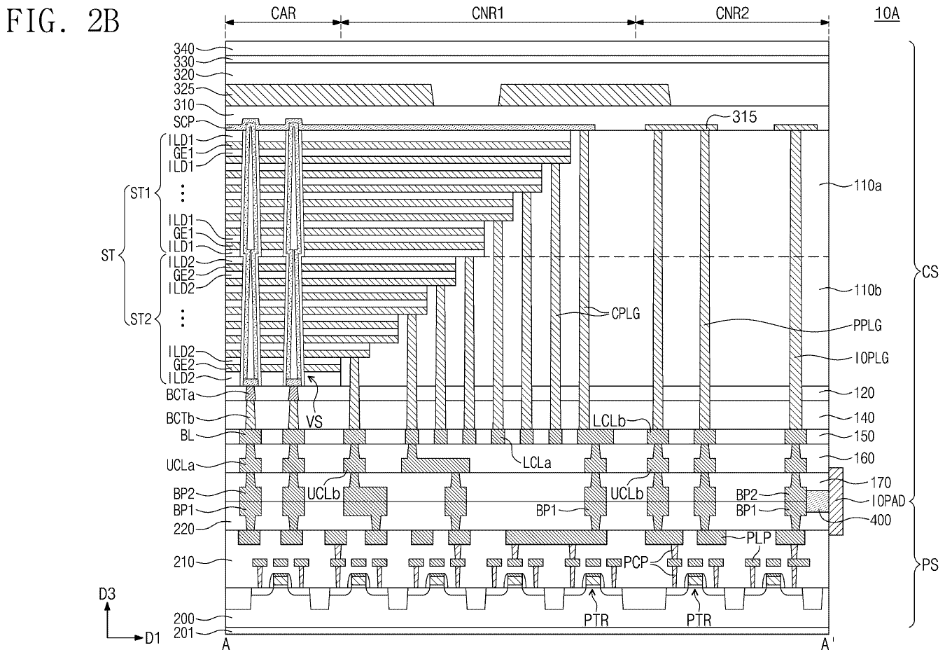

FIG. 2A is a plan view illustrating a semiconductor device according to an example embodiment of the inventive concept. FIG. 2B is a sectional view taken along a line A-A′ of FIG. 2A to illustrate a semiconductor device according to an example embodiment of the inventive concept.

Referring to FIGS. 2A and 2B, a semiconductor device 10A may include a peripheral circuit structure PS on a substrate 200 and a cell array structure CS on the peripheral circuit structure PS.

In an embodiment, since the cell array structure CS is placed on the peripheral circuit structure PS, a cell capacity per unit area in the semiconductor device may be increased. In addition, the peripheral circuit structure PS and the cell array structure CS may be separately fabricated and then may be coupled to each other, and in this case, it may be possible to prevent peripheral circuits PTR from being damaged by various thermal treatment processes.

The peripheral circuit structure PS may include the substrate 200, the peripheral circuits PTR controlling a memory cell array, and the first and second peripheral interlayer insulating layers 210 and 220. The peripheral circuits PTR may be integrated on a surface of the substrate 200. A surface insulating layer 201 may be provided on a bottom or rear surface of the substrate 200.

The substrate 200 may be a silicon substrate, a silicon-germanium substrate, a germanium substrate, or a structure including a single-crystalline silicon substrate and a single crystalline epitaxial layer grown therefrom. The substrate 200 may have a top surface that is parallel to two different directions (e.g., a first direction D1 and a second direction D2) and is perpendicular to a third direction D3. For example, the first to third directions D1, D2, and D3 may be orthogonal to each other.

The peripheral circuits PTR may include row and column decoders, a page buffer, a control circuit, and so forth. In detail, the peripheral circuits PTR may include NMOS and PMOS transistors. Peripheral circuit lines PLP may be electrically connected to the peripheral circuits PTR through peripheral contact plugs PCP.

A width of the peripheral contact plug PCP in the first or second direction D1 or D2 may increase, as a distance from the substrate 200 increases. The peripheral contact plugs PCP and the peripheral circuit lines PLP may be formed of or include at least one of conductive materials (e.g., metallic materials).

The first and second peripheral interlayer insulating layers 210 and 220 may be provided on a top surface of the substrate 200. The first peripheral interlayer insulating layer 210 may be provided on the top surface of the substrate 200 to cover the peripheral circuits PTR, the peripheral contact plugs PCP, and the peripheral circuit lines PLP. The peripheral contact plugs PCP and the peripheral circuit lines PLP may be electrically connected to the peripheral circuits PTR.

The second peripheral interlayer insulating layer 220 may be disposed on the first peripheral interlayer insulating layer 210. First bonding pads BP1 may be disposed in the second peripheral interlayer insulating layer 220. The second peripheral interlayer insulating layer 220 may not cover top surfaces of the first bonding pads BP1. A top surface of the second peripheral interlayer insulating layer 220 may be substantially coplanar with the top surfaces of the first bonding pads BP1. The first bonding pads BP1 may be electrically connected to the peripheral circuits PTR through the peripheral circuit lines PLP and the peripheral contact plugs PCP. In an embodiment, each of the first and second peripheral interlayer insulating layers 210 and 220 may be formed of or include a silicon oxide layer, a silicon nitride layer, a silicon oxynitride layer, and/or a low-k dielectric layer.

The cell array structure CS may be provided on the peripheral circuit structure PS. The cell array structure CS of the semiconductor device may include a cell array region CAR and first and second connection regions CNR1 and CNR2, and the first connection region CNR1 may be placed between the cell array region CAR and the second connection region CNR2 in the first direction D1.

The cell array structure CS may include a memory cell array, in which memory cells are three-dimensionally arranged. The cell array structure CS may include a source conductive pattern SCP, a stack ST, vertical structures VS, the bit lines BL, cell contact plugs CPLG, and peripheral contact plugs PPLG.

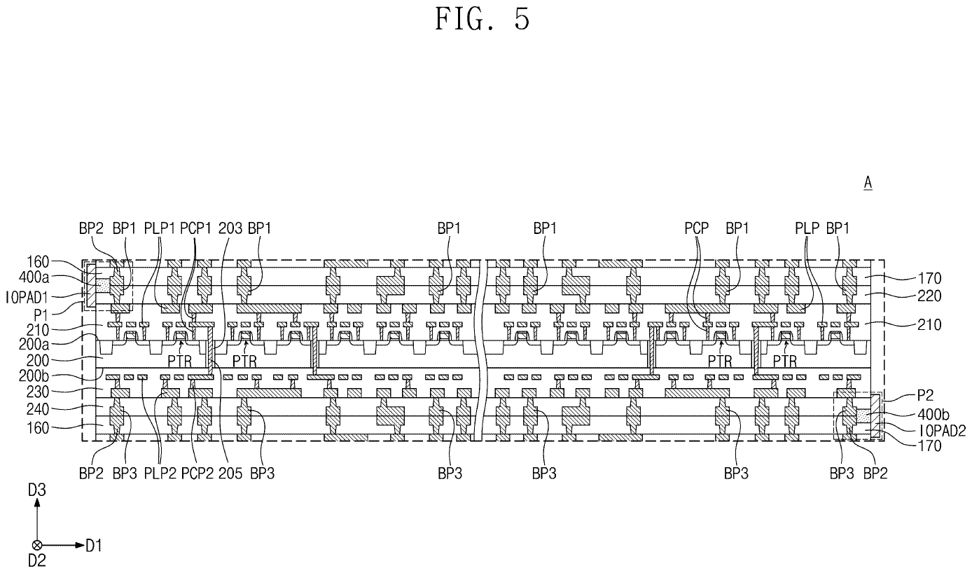

The cell array structure CS may include a plurality of stacks ST. When viewed in the plan view of FIG. 5, the stacks ST may be extended lengthwise in the first direction D1 and may be spaced apart from each other in the second direction D2. Hereinafter, just one stack ST will be described, for brevity's sake, but the others of the stacks ST may also have substantially the same features as described below.

The stack ST may include gate patterns GE1 and GE2 and insulating patterns ILD1 and ILD2, which are alternately stacked in the third direction D3 (e.g., a vertical direction) that is perpendicular to the first and second directions D1 and D2.

In an embodiment, the gate patterns GE1 and GE2 may include first and second erase gate patterns adjacent to the source conductive pattern SCP, a ground selection gate pattern on the second erase gate pattern, a plurality of cell gate patterns stacked on the ground selection gate pattern, and a string selection gate pattern on the uppermost one of the cell gate patterns.

The gate patterns GE1 and GE2 of the stack ST may be stacked to have an inverted staircase structure in the first connection region CNR1. That is, lengths of the gate patterns GE1 and GE2 in the first direction D1 may increase, as a distance from the peripheral circuit structure PS increases.

Each of the gate patterns GE1 and GE2 may include a pad portion in the first connection region CNR1. The pad portions of the gate patterns GE1 and GE2 may be located at different positions in horizontal and vertical directions. The cell contact plugs CPLG may be coupled to the pad portions of the gate patterns GE1 and GE2, respectively.

In an embodiment, the stack ST may include a first stack ST1 and a second stack ST2 connected to the first stack ST1. The first stack ST1 may include first insulating patterns ILD1 and first gate patterns GE1, which are alternately stacked on top of each other, and the second stack ST2 may include second insulating patterns ILD2 and second gate patterns GE2, which are alternately stacked on top of another.

The second stack ST2 may be disposed between the first stack ST1 and the peripheral circuit structure PS. More specifically, the second stack ST2 may be provided on a bottom surface of the bottommost one of the first insulating patterns ILD1 of the first stack ST1. The topmost one of the second insulating patterns ILD2 of the second stack ST2 may be in contact with the bottommost one of the first insulating patterns ILD1 of the first stack ST1, but the inventive concept is not limited to this example. A single insulating layer may be provided between the topmost one of the second gate patterns GE2 of the second stack ST2 and the first gate patterns GE1 of the first stack ST1.

The bottommost one of the second gate patterns GE2 of the second stack ST2 may have the smallest length in the first direction D1, and the topmost one of the first gate patterns GE1 of the first stack ST1 may have the largest length in the first direction D1.

The first and second gate patterns GE1 and GE2 may be formed of or include at least one of, for example, doped semiconductor materials (e.g., doped silicon and so forth), metallic materials (e.g., tungsten, molybdenum, nickel, copper, aluminum, and so forth), conductive metal nitrides (e.g., titanium nitride, tantalum nitride, and so forth), or transition metals (e.g., titanium, tantalum, and so forth). The first and second insulating patterns ILD1 and ILD2 may be formed of or include at least one of silicon oxide, silicon nitride, silicon oxynitride, and/or low-k dielectric materials. In an embodiment, the first and second insulating patterns ILD1 and ILD2 may include at least one of high density plasma (HDP) oxide or tetraethyl orthosilicate (TEOS).

In an embodiment, the semiconductor device may be a vertical-type NAND FLASH memory device, and in this case, the first and second gate patterns GE1 and GE2 of the stack ST may be used as the gate lower lines LL1 and LL2, the word lines WL, and the gate upper lines UL1 and UL2 described with reference to FIG. 1.

Planarization insulating layers 110a and 110b may be provided to cover a stepwise structure, which is formed by end portions (i.e., the pad portions) of the stack ST. Each of the planarization insulating layers 110a and 110b may have a substantially flat top surface. The planarization insulating layers 110a and 110b may include an insulating layer or a plurality of stacked insulating layers. In an embodiment, the planarization insulating layers 110a and 110b may include a first planarization insulating layer 110a, which covers the staircase structure of the first stack ST1, and a second planarization insulating layer 110b, which covers the staircase structure of the second stack ST2. The planarization insulating layers 110a and 110b may have top and bottom surfaces that are substantially flat. The planarization insulating layers 110a and 110b may have top surfaces that are substantially coplanar with a top surface of the uppermost one of the insulating patterns ILD1 of the stack ST, and the planarization insulating layers 110a and 110b may have bottom surfaces that are substantially coplanar with a bottom surface of the lowermost one of the insulating patterns ILD2 of the stack ST.

The source conductive pattern SCP may be disposed on the uppermost one of the first insulating patterns ILD1 of the first stack ST1. The source conductive pattern SCP may contact the uppermost one of the first insulating patterns ILD1 and a portion of a top surface of the first planarization insulating layer 110a. The source conductive pattern SCP may correspond to the common source line CSL of FIG. 1. The source conductive pattern SCP may have a uniform thickness. In the cell array region CAR and the first connection region CNR1, the source conductive pattern SCP may be extended in the first and second directions D1 and D2. When measured in the first direction D1, a length of the source conductive pattern SCP may be larger than a length of the uppermost one of the first gate patterns GE1 of the first stack ST1.

In the second connection region CNR2, first upper conductive patterns 315 may be disposed on a top surface of the first planarization insulating layer 110a and may be placed at substantially the same level as the source conductive pattern SCP. The first upper conductive patterns 315 may contact the top surface of the first planarization insulating layer 110a. The first upper conductive patterns 315 may include the same conductive material as the source conductive pattern SCP.

The vertical structures VS may penetrate the stack ST in the cell array region CAR and may be connected to the source conductive pattern SCP. When viewed in a plan view, the vertical structures VS may be arranged in a specific direction or in a zigzag shape.

Dummy vertical structures DVS may be provided to penetrate the stack ST in the first connection region CNR1. The dummy vertical structures DVS may be provided to penetrate end portions (i.e., pad portions) of the first and second gate patterns GE1 and GE2 in the first connection region CNR1. The dummy vertical structures DVS may have substantially the same structure as the vertical structures VS and may include substantially the same materials as the vertical structures VS.

The dummy vertical structures DVS may differ from the vertical structures VS in terms of planar shape and size. When viewed in a plan view, the top surfaces of the dummy vertical structures DVS may have various shapes (e.g., circular, elliptical, and bar shapes). The dummy vertical structures DVS may be disposed around each cell contact plug CPLG, when viewed in a plan view. In an embodiment, a plurality of dummy vertical structures DVS may be provided between adjacent ones of the cell contact plugs CPLG. In example embodiments, the dummy vertical structures DVS are not effective to function for read or write operations. For example, dummy vertical structures DVS may not be electrically connected to bit line contacts, and therefore cannot connect to bit lines.

In an embodiment, each of the vertical structures VS may be provided in a vertical channel hole penetrating the stack ST. In an embodiment, the vertical channel hole may include a first vertical channel hole, which is provided to penetrate the first stack ST1, and a second vertical channel hole, which is provided to penetrate the second stack ST2 and is connected to the first vertical channel hole.

Each of the vertical structures VS may include a first vertical extended portion in the first vertical channel hole and a second vertical extended portion in the second vertical channel hole. The first and second vertical extended portions may be a single object that is continuously extended without any interface therein. Here, the first vertical extended portion may have a side surface with a substantially constant slope from bottom to top. Similarly, the second vertical extended portion may have a side surface whose slope is substantially constant from top to bottom. That is, each of the first and second vertical extended portions may have a decreasing width in the first or second direction D1 or D2, as a distance from the substrate 200 increases. The first and second vertical extended portions may have different diameters from each other, at a level where they are connected to each other. The first and second vertical extended portions may form a stepwise or staircase structure at the level where they are connected to each other.

However, the inventive concept is not limited to this example, and in an embodiment, each vertical structure VS may include three or more vertical extended portions, which are provided to form the stepwise structure at two or more levels, unlike that illustrated in the drawings. Alternatively, each vertical structure VS may be provided to have a flat side surface without any stepwise portion.

Each of the vertical structures VS may include a vertical channel pattern, a data storage pattern, and a vertical insulating pattern.

The vertical channel pattern may be provided to have a pipe or macaroni shape with closed top and bottom ends. The vertical channel pattern may have an inner side surface, which defines an internal space, and an outer side surface, which is adjacent to the stack ST. The vertical channel pattern may be provided to enclose an outer side surface of the vertical insulating pattern, and a portion of the vertical channel pattern may be disposed between the source conductive pattern SCP and the vertical insulating pattern.

The vertical channel pattern may be formed of or include at least one of semiconductor materials (e.g., silicon (Si) and germanium (Ge)). The vertical channel pattern, which includes the semiconductor material, may be used as the channel regions of the upper transistors UT1 and UT2, the memory cell transistors MCT, and the lower transistors LT1 and LT2 described with reference to FIG. 1.

The data storage pattern may be extended in the third direction D3 to enclose an outer side surface of each vertical channel pattern. A top surface of the data storage pattern may be located at a level lower than a top surface of the vertical channel pattern. The data storage pattern may be a pipe or macaroni structure with an open top. The data storage pattern may be composed of one or more layers. In an embodiment, the data storage pattern may be a data storing layer of a NAND FLASH memory device and may include a tunnel insulating layer, a charge storing layer, and a blocking insulating layer, which are sequentially stacked on a side surface of the vertical channel pattern. For example, the charge storing layer may be a trap insulating layer, a floating gate electrode, or an insulating layer including conductive nanodots.

A bit line conductive pad may be provided under a bottom end of the vertical structure VS. The bit line conductive pad may be formed of an undoped semiconductor material, a doped semiconductor material, or a conductive material.

First, second, and third separation structures SS1, SS2, and SS3 may be provided to extend lengthwise in the first direction D1. Although not shown, the first, second, and third separation structures SS1, SS2, and SS3 may be provided to penetrate a first interlayer insulating layer 120, the planarization insulating layers 110a and 110b, and the stack ST. Each of the first, second, and third separation structures SS1, SS2, and SS3 may have a single-or multi-layered structure. In an embodiment, the first, second, and third separation structures SS1, SS2, and SS3 may be formed of or include at least one of insulating materials (e.g., silicon oxide, silicon oxynitride, and silicon nitride).

The first separation structures SS1 may be extended lengthwise in the first direction D1 from the cell array region CAR to the first connection region CNR1 to be parallel to each other and may be spaced apart from each other in the second direction D2 crossing the first direction D1. In an embodiment, the stack ST may be disposed between the first separation structures SS1, which are adjacent to each other in the second direction D2.

The second separation structure SS2 may be provided in the cell array region CAR to penetrate the stack ST. The second separation structure SS2 may be disposed between the first separation structures SS1. When measured in the first direction D1, a length of the second separation structure SS2 may be smaller than a length of the first separation structure SS1. Alternatively, a plurality of second separation structures SS2 may be provided between the first separation structures SS1.

In the first connection region CNR1, the third separation structures SS3 may be spaced apart from the first and second separation structures SS1 and SS2 in the second direction D2 and may penetrate the planarization insulating layers 110a and 110b and the stack ST. The third separation structures SS3 may be extended in the first direction D1. The third separation structures SS3 may be spaced apart from each other in the first and second directions D1 and D2.

The first interlayer insulating layer 120 may be disposed on a bottom surface of the planarization insulating layer 110b and a bottom surface of the stack ST. The first interlayer insulating layer 120 may cover bottom surfaces of the vertical structures VS. For example, the first interlayer insulating layer 120 may contact the bottom surface of the planarization insulating layer 110b and the bottom surfaces of the vertical structures VS.

First bit line contact plugs BCTa may be disposed in the first interlayer insulating layer 120. The first bit line contact plugs BCTa may be provided to penetrate the first interlayer insulating layer 120 and may be electrically connected to the bit line conductive pad.

A second interlayer insulating layer 140 may be disposed on a bottom surface of the first interlayer insulating layer 120. Second bit line contact plugs BCTb may be disposed in the second interlayer insulating layer 140. The second bit line contact plugs BCTb may be provided to penetrate the second interlayer insulating layer 140 and may be coupled to the first bit line contact plugs BCTa. For example, the second bit line contact plugs BCTb may contact bottom surfaces of the first bit line contact plugs BCTa.

In the first connection region CNR1, the cell contact plugs CPLG may be provided to penetrate the first and second interlayer insulating layers 120 and 140 and the planarization insulating layers 110a and 110b and may be respectively coupled to pad portions of the first and second gate patterns GE1 and GE2. The smaller the distance to the cell array region CAR, the smaller the vertical lengths of the cell contact plugs CPLG. Bottom surfaces of the cell contact plugs CPLG may be substantially coplanar with each other.

Peripheral contact plugs PPLG and input/output contact plugs IOPLG may be provided in the second connection region CNR2 to penetrate the first and second interlayer insulating layers 120 and 140 and the planarization insulating layers 110a and 110b and may be coupled to the first upper conductive patterns 315. In another embodiment, the input/output contact plugs IOPLG may be omitted.

Each of the cell, peripheral, and input/output contact plugs CPLG, PPLG, and IOPLG may include a barrier metal layer, which is formed of or includes a conductive metal nitride material (e.g., titanium nitride and tantalum nitride), and a metal layer, which is formed of or includes a metallic material (e.g., tungsten, titanium, and tantalum).

A third interlayer insulating layer 150 may be disposed on a bottom surface of the second interlayer insulating layer 140. The bit lines BL and first and second lower conductive lines LCLa and LCLb may be disposed in the third interlayer insulating layer 150.

In the cell array region CAR, the bit lines BL may be disposed on the bottom surface of the second interlayer insulating layer 140. The bit lines BL may be extended lengthwise in the second direction D2 to cross the stack ST. The bit lines BL may be electrically connected to the vertical structures VS through the first and second bit line contact plugs BCTa and BCTb.

In the first connection region CNR1, the first lower conductive lines LCLa may be disposed on the bottom surface of the second interlayer insulating layer 140. The first lower conductive lines LCLa may be coupled to the cell contact plugs CPLG. The first lower conductive lines LCLa may contact the cell contact plugs CPLG.

In the second connection region CNR2, the second lower conductive lines LCLb may be disposed on the second interlayer insulating layer 140. The second lower conductive lines LCLb may be coupled to the peripheral and input/output contact plugs PPLG and IOPLG. The second lower conductive lines LCLb may contact the peripheral and input/output contact line plugs PPLG and IOPLG.

A fourth interlayer insulating layer 160 may be disposed on a bottom surface of the third interlayer insulating layer 150. First and second upper conductive lines UCLa and UCLb may be disposed in the fourth interlayer insulating layer 160. The first upper conductive lines UCLa may be electrically connected to the bit lines BL, in the cell array region CAR. The second upper conductive lines UCLb may be electrically connected to the first and second lower conductive lines LCLa and LCLb, in the first and second connection regions CNR1 and CNR2.

The first and second lower conductive lines LCLa and LCLb and the first and second upper conductive lines UCLa and UCLb may be formed of or include at least one of, for example, metallic materials (e.g., tungsten, copper, and aluminum), conductive metal nitride materials (e.g., titanium nitride and tantalum nitride), or transition metals (e.g., titanium and tantalum). For example, the first and second lower conductive lines LCLa and LCLb may be formed of or include a material (e.g., tungsten) having relatively high electric resistivity, and the first and second upper conductive lines UCLa and UCLb may be formed of or include a material (e.g., copper) having relatively low electric resistivity.

A fifth interlayer insulating layer 170 may be disposed on a bottom surface of the fourth interlayer insulating layer 160. Second bonding pads BP2 may be disposed in the fifth interlayer insulating layer 170. The second bonding pads BP2 may be electrically connected to the first and second upper conductive lines UCLa and UCLb. The second bonding pads BP2 may be formed of or include aluminum, copper, or tungsten.

The second bonding pads BP2 may be electrically and physically connected to the first bonding pads BP1 by a bonding method. For example, the second bonding pads BP2 may be in direct contact with the first bonding pads BP1.

The second bonding pads BP2 may include the same metallic material as the first bonding pads BP1. The second bonding pads BP2 may be substantially the same as the first bonding pads BP1 in terms of shape, width, and/or area.

The first and second bonding pads BP1 and BP2 may be provided to face each other and form a hybrid bonding structure. For example, the first and second bonding pads BP1 and BP2 may be bonded to form a single object with a faint or transparent interface, but the inventive concept is not limited to this example.

Input/output pads IOPAD may be disposed on a side surface of the cell array structure CS and a side surface of the peripheral circuit structure PS. The input/output pad IOPAD may be used as the input/output pad 1101 described with reference to FIG. 1 and may be used for the communication with an external controller. In an embodiment, the input/output pads IOPAD may be spaced apart from each other in the second direction D2 and may be disposed on a side surface of the fifth interlayer insulating layer 170 and a side surface of the second peripheral interlayer insulating layer 220. The input/output pads IOPAD may contact side surfaces of the fifth interlayer insulating layer 170 and the second peripheral interlayer insulating layer 220. The input/output pad IOPAD may be electrically connected to the first and second bonding pads BP1 and BP2 through a conductive contact 400, which will be described below. In an embodiment, the input/output pads IOPAD may be extended in the third direction D3 and may be in partial contact with side surfaces of the fourth interlayer insulating layer 160 and the first peripheral interlayer insulating layer 210, but the inventive concept is not limited to this example.

Conductive contacts 400 may be disposed between the input/output pads IOPAD and the first and second bonding pads BP1 and BP2. For example, the conductive contact 400 may be disposed between the first and second bonding pads BP1 and BP2, which are located in an end portion of the second connection region CNR2 in the first direction D1, and the input/output pad IOPAD. The conductive contact 400 may be disposed in the fifth interlayer insulating layer 170 and the second peripheral interlayer insulating layer 220. A side portion of the conductive contact 400 may be in contact with side surfaces of the first and second bonding pads BP1 and BP2. An opposite side portion of the conductive contact 400 may be in contact with the input/output pad IOPAD.

In an embodiment, the input/output pads IOPAD and the conductive contacts 400 may be formed of or include at least one of metallic materials (e.g., tungsten, copper, and aluminum), conductive metal nitride materials (e.g., titanium nitride and tantalum nitride), or transition metal materials (e.g., titanium and tantalum).

A first upper insulating layer 310 may be provided to cover the source conductive pattern SCP and the first upper conductive patterns 315. A second upper insulating layer 320 may be disposed on the first upper insulating layer 310. Second upper conductive patterns 325 may be disposed in the second upper insulating layer 320. In an embodiment, the first and second upper conductive patterns 315 and 325 may be formed of or include at least one of, for example, metallic materials (e.g., tungsten, copper, and aluminum), conductive metal nitride materials (e.g., titanium nitride and tantalum nitride), or transition metals (e.g., titanium and tantalum).

A capping insulating layer 330 and a passivation layer 340 may be sequentially formed on the second upper insulating layer 320. The capping insulating layer 330 may be, for example, a silicon nitride layer or a silicon oxynitride layer. The passivation layer 340 may be formed of or include polyimide-based materials (e.g., photo sensitive polyimide (PSPI)).

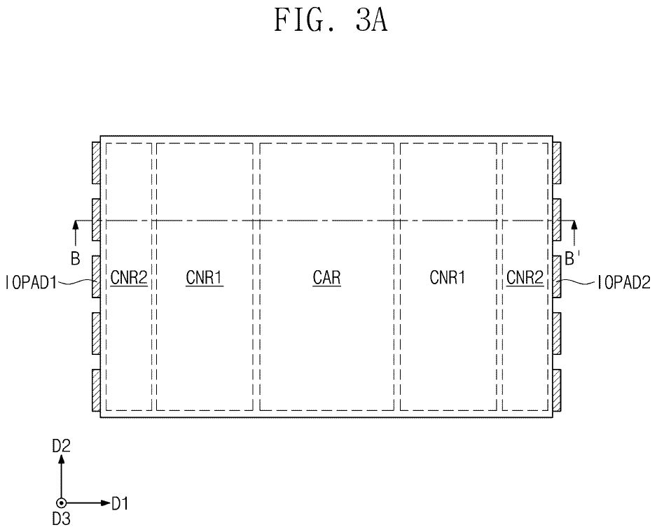

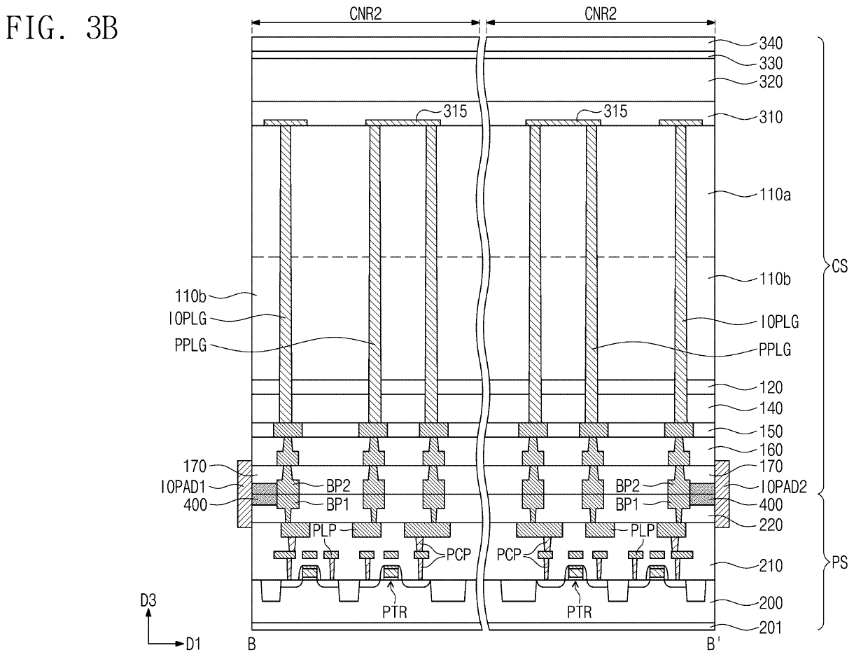

FIG. 3A is a plan view illustrating a semiconductor device according to an example embodiment of the inventive concept. FIG. 3B is a sectional view taken along a line B-B′ of FIG. 3A to illustrate a semiconductor device according to an example embodiment of the inventive concept. In the following description, previously described elements may be identified by the same reference number without repeating an overlapping description thereof, for the sake of brevity.

Referring to FIGS. 3A and 3B, first connection regions CNR1, second connection regions CNR2, and the cell array region CAR may be arranged in the first direction D1. In more detail, the second connection regions CNR2 may be placed in opposite end portions of the semiconductor device in the first direction D1. The cell array region CAR may be placed between the second connection regions CNR2. Each of the first connection regions CNR1 may be placed between the cell array region CAR and the second connection region CNR2.

Input/output pads IOPAD1 and IOPAD2 may be disposed on opposite side surfaces of the semiconductor device. In detail, first input/output pads IOPAD1 may be disposed on a first side surface of the semiconductor device, and second input/output pads IOPAD2 may be disposed on a second side surface of the semiconductor device. In an embodiment, the semiconductor device may have a first side surface and a second side surface that are opposite to each other. The first and second input/output pads IOPAD1 and IOPAD2 may be spaced apart from each other in the second direction D2 and may be disposed on opposite side surfaces of the fifth interlayer insulating layer 170 and opposite side surfaces of the second peripheral interlayer insulating layer 220. The first and second input/output pads IOPAD1 and IOPAD2 may be electrically connected to the first and second bonding pads BP1 and BP2, respectively, through the conductive contact 400.

The first and second input/output pads IOPAD1 and IOPAD2 may be used as the input/output pad IOPAD described with reference to FIGS. 2A and 2B and may be used for the communication with an external controller. In an embodiment, voltages may be applied to the semiconductor device through the first and second input/output pads IOPAD1 and IOPAD2.

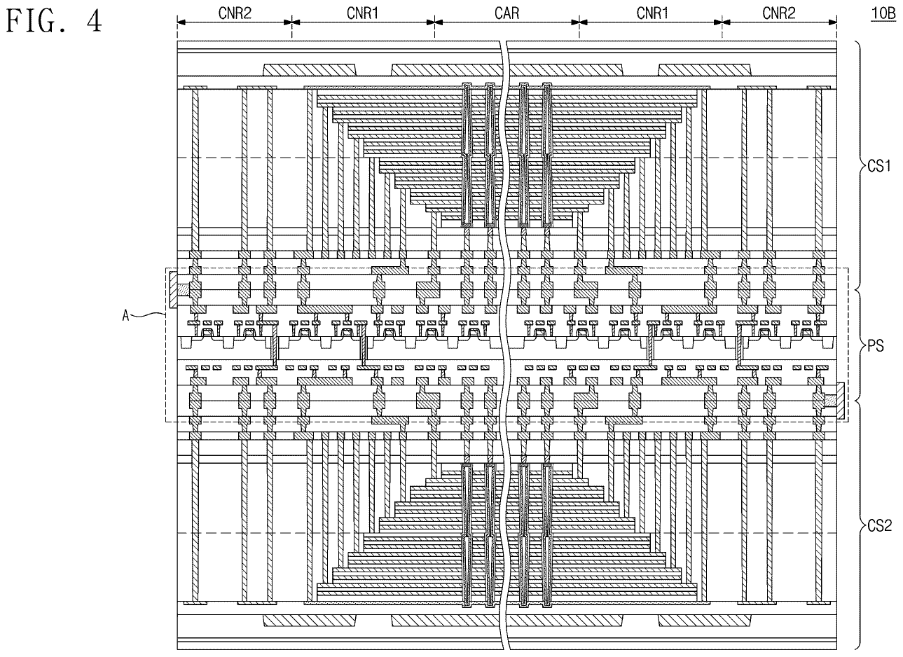

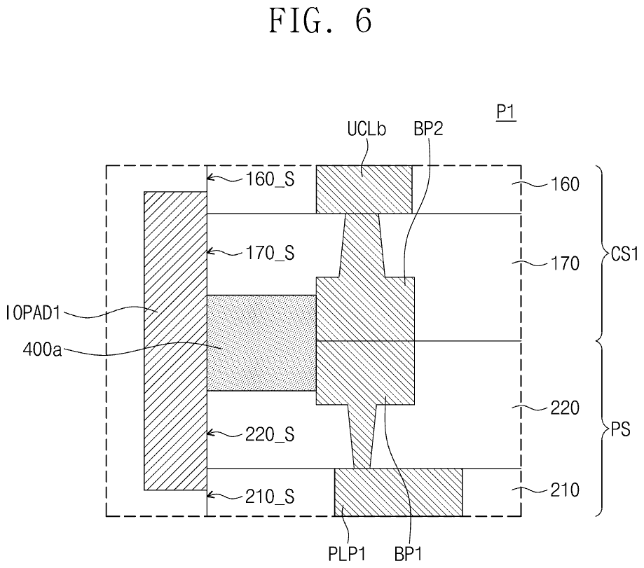

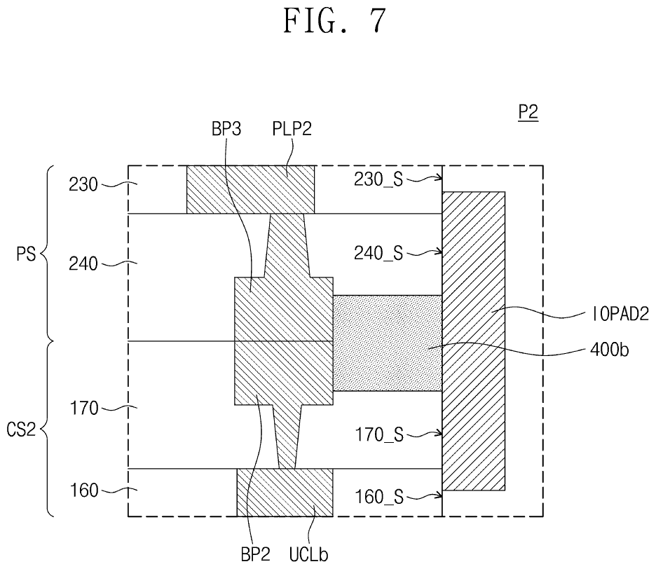

FIG. 4 is a sectional view illustrating a semiconductor device according to an example embodiment of the inventive concept. FIG. 5 is an enlarged sectional view illustrating a portion ‘A’ of FIG. 4. FIG. 6 is an enlarged sectional view illustrating a portion ‘P1’ of FIG. 5. FIG. 7 is an enlarged sectional view illustrating a portion ‘P2’ of FIG. 5.

Referring to FIGS. 4 and 5, a semiconductor device 10B may include a peripheral circuit structure PS, a first cell array structure CS1, and a second cell array structure CS2. Each of the first and second cell array structures CS1 and CS2 may be substantially the same as the cell array structure CS described with reference to FIG. 2B. That is, each of the first and second cell array structures CS1 and CS2 may include the source conductive pattern SCP, the stack ST, the vertical structures VS, the bit lines BL, the cell contact plugs CPLG, and the peripheral contact plugs PPLG described with reference to FIG. 2B.

The first and second cell array structures CS1 and CS2 may include memory cell arrays that are different from each other. That is, the memory cell arrays of the first and second cell array structures CS1 and CS2 may be separately or independently controlled. In an embodiment, the memory cell array of the first cell array structure CS1 may be controlled by some of the peripheral circuits PTR of the peripheral circuit structure PS, and the memory cell array of the second cell array structure CS2 may be controlled by others of the peripheral circuits PTR of the peripheral circuit structure PS.

Although not shown in the drawings, the first and second cell array structures CS1 and CS2 may share a voltage generator (not shown). The voltage generator may be configured to provide a program voltage, a read voltage, a pass voltage, and a verify voltage, which are required to operate the memory cell array.

The peripheral circuit structure PS may include the substrate 200 having a first surface 200a and a second surface 200b, which are opposite to each other. The first cell array structure CS1 may be disposed on the first surface 200a of the substrate 200, and the second cell array structure CS2 may be disposed on the second surface 200b of the substrate 200. The peripheral circuits PTR may be formed on the first surface 200a of the substrate 200, some of the peripheral circuits PTR may be configured to control the first cell array structure CS1, and others of the peripheral circuits PTR may be configured to control the second cell array structure CS2.

The first and second peripheral interlayer insulating layers 210 and 220 may be disposed on the first surface 200a of the substrate 200. First peripheral contact plugs PCP1 and first peripheral circuit lines PLP1, which are connected to a portion of the peripheral circuits PTR, may be disposed in the first peripheral interlayer insulating layer 210. A portion of the peripheral circuits PTR may be electrically connected to the first peripheral circuit lines PLP1 through the first peripheral contact plugs PCP1. The first peripheral contact plugs PCP1 and the first peripheral circuit lines PLP1 may include at least one of conductive materials (e.g., metallic materials).

The first and second peripheral interlayer insulating layers 210 and 220 may be provided on the first surface 200a of the substrate 200. The first peripheral interlayer insulating layer 210 may be provided on the first surface 200a of the substrate 200 to cover the peripheral circuits PTR, the first peripheral contact plugs PCP1, and the first peripheral circuit lines PLP1. The second peripheral interlayer insulating layer 220 may be disposed on the first peripheral interlayer insulating layer 210. The first bonding pads BP1 may be disposed in the second peripheral interlayer insulating layer 220. The second peripheral interlayer insulating layer 220 may not cover the top surfaces of the first bonding pads BP1. The top surface of the second peripheral interlayer insulating layer 220 may be substantially coplanar with the top surfaces of the first bonding pads BP1. The first bonding pads BP1 may be electrically connected to the peripheral circuits PTR through the first peripheral circuit lines PLP1 and the first peripheral contact plugs PCP1.

The peripheral circuit structure PS may further include penetration via patterns 205 penetrating the substrate 200. Each of the penetration via patterns 205 may be provided to penetrate the substrate 200 vertically (e.g., in the third direction D3). The penetration via patterns 205 may be electrically connected to another portion of the peripheral circuits PTR (e.g., disconnected from the first cell array structure CS1) through the first peripheral circuit lines PLP1 and the first peripheral contact plugs PCP1. The penetration via patterns 205 may be provided to penetrate the substrate 200 and may be electrically connected to second peripheral circuit lines PLP2 and second peripheral contact plugs PCP2, which will be described below.

A penetration insulating pattern 203 may be disposed between the penetration via patterns 205 and the substrate 200. The penetration insulating pattern 203 may contact side surfaces of the penetration via patterns 205, and may electrically insulate the penetration via patterns 205 from the substrate 200. In an embodiment, the penetration insulating pattern 203 may include a silicon-based insulating material.

Third and fourth peripheral interlayer insulating layers 230 and 240 may be disposed on the second surface 200b of the substrate 200. The second peripheral contact plugs PCP2 and the second peripheral circuit lines PLP2, which are connected to another portion of the peripheral circuits PTR, may be disposed in the third peripheral interlayer insulating layer 230. Others of the peripheral circuits PTR may be electrically connected to the second peripheral circuit lines PLP2 via the second peripheral contact plugs PCP2. The second peripheral contact plugs PCP2 and the second peripheral circuit lines PLP2 may include at least one of conductive materials (e.g., metallic materials).

The third and fourth peripheral interlayer insulating layers 230 and 240 may be provided on the second surface 200b of the substrate 200. The third peripheral interlayer insulating layer 230 may be disposed on the second surface 200b of the substrate 200 to cover the second peripheral contact plugs PCP2 and the second peripheral circuit lines PLP2. The fourth peripheral interlayer insulating layer 240 may be disposed on a bottom surface of the third peripheral interlayer insulating layer 230. Third bonding pads BP3 may be disposed in the fourth peripheral interlayer insulating layer 240. The fourth peripheral interlayer insulating layer 240 may not cover bottom surfaces of the third bonding pads BP3. A bottom surface of the fourth peripheral interlayer insulating layer 240 may be substantially coplanar with bottom surfaces of the third bonding pads BP3. The third bonding pads BP3 may be electrically connected to the peripheral circuits PTR through the second peripheral circuit lines PLP2, the second peripheral contact plugs PCP2, and the penetration via patterns 205. As an example, each of the first to fourth peripheral interlayer insulating layers 210, 220, 230, and 240 may include a silicon oxide layer, a silicon nitride layer, a silicon oxynitride layer, and/or a low-k dielectric layer.

Referring to FIGS. 4 to 6, the second bonding pads BP2 of the first cell array structure CS1 may be attached to the first bonding pads BP1 of the peripheral circuit structure PS. In an embodiment, the second bonding pads BP2 of the first cell array structure CS1 and the first bonding pads BP1 of the peripheral circuit structure PS may form a hybrid bonding structure.

The first input/output pads IOPAD1 may be disposed on a side surface of the first cell array structure CS1 and a first side surface of the peripheral circuit structure PS. In detail, the first input/output pads IOPAD1 may be disposed on a side surface 170_S of the fifth interlayer insulating layer 170 of the first cell array structure CS1 and a side surface 220_S of the second peripheral interlayer insulating layer 220 of the peripheral circuit structure PS. For example, the first input/output pads IOPAD1 may contact the side surface 170_S of the fifth interlayer insulating layer 170 and the side surface 220_S of the second peripheral interlayer insulating layer 220. The first input/output pads IOPAD1 may be electrically connected to the second bonding pads BP2 of the first cell array structure CS1 and the first bonding pads BP1 of the peripheral circuit structure PS through first conductive contacts 400a. The first input/output pads IOPAD1 may contact the first conductive contacts 400a. The first input/output pads IOPAD1 may be used for the communication with an external controller and may be electrically connected to the first cell array structure CS1. In an embodiment, the first input/output pads IOPAD1 may be spaced apart from each other in the second direction D2.

The first conductive contacts 400a may be disposed between the first input/output pads IOPAD1 and the second bonding pads BP2 of the first cell array structure CS1 and between the first input/output pads IOPAD1 and the first bonding pads BP1 of the peripheral circuit structure PS. The first conductive contact 400a may be disposed in the fifth interlayer insulating layer 170 of the first cell array structure CS1 and the second peripheral interlayer insulating layer 220 of the peripheral circuit structure PS.

Referring to FIGS. 4, 5, and 7, the second bonding pads BP2 of the second cell array structure CS2 and the third bonding pads BP3 of the peripheral circuit structure PS may be attached to each other. In an embodiment, the second bonding pads BP2 of the second cell array structure CS2 and the third bonding pads BP3 of the peripheral circuit structure PS may form a hybrid bonding structure.

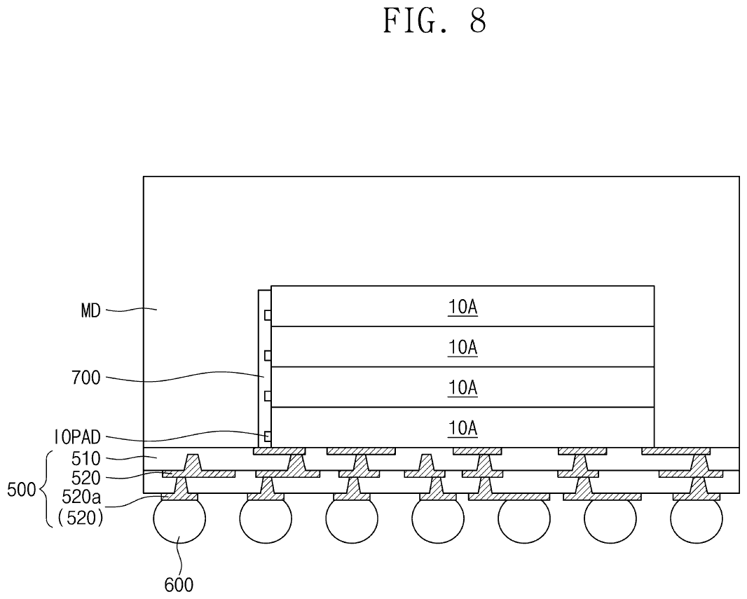

The second input/output pads IOPAD2 may be disposed on a side surface of the second cell array structure CS2 and a second side surface of the peripheral circuit structure PS. In an embodiment, the second side surface of the peripheral circuit structure PS may be a side surface that is opposite to the first side surface of the peripheral circuit structure PS described with reference to FIG. 8B. In addition, the second input/output pads IOPAD2 may be disposed on the side surface 170_S of the fifth interlayer insulating layer 170 of the second cell array structure CS2 and a side surface 240_S of the fourth peripheral interlayer insulating layer 240 of the peripheral circuit structure PS. For example, the second input/output pads IOPAD2 may contact the side surface 170_S of the fifth interlayer insulating layer 170 and the side surface 240_S of the fourth peripheral interlayer insulating layer 240. The second input/output pads IOPAD2 may be electrically connected to the second bonding pads BP2 of the second cell array structure CS2 and the third bonding pads BP3 of the peripheral circuit structure PS through second conductive contacts 400b. The second input/output pads IOPAD2 may contact the second conductive contacts 400b. The second input/output pad IOPAD2 may be used for the communication with an external controller and may be electrically connected to the second cell array structure CS2. In an embodiment, the second input/output pads IOPAD2 may be spaced apart from each other in the second direction D2.

The second conductive contacts 400b may be disposed between the second input/output pads IOPAD2 and the second bonding pads BP2 of the second cell array structure CS2 and between the second input/output pads IOPAD2 and the third bonding pads BP3 of the peripheral circuit structure PS. The second conductive contact 400b may be disposed in the fifth interlayer insulating layer 170 of the second cell array structure CS2 and the fourth peripheral interlayer insulating layer 240 of the peripheral circuit structure PS.

In an embodiment, the first and second input/output pads IOPAD1 and IOPAD2 and the first and second conductive contacts 400a and 400b may be formed of or include at least one of, for example, metallic materials (e.g., tungsten, copper, and aluminum), conductive metal nitride materials (e.g., titanium nitride and tantalum nitride), or transition metals (e.g., titanium and tantalum).

FIG. 8 is a sectional view illustrating a semiconductor package according to an example embodiment of the inventive concept.

Referring to FIG. 8, a package substrate 500 may be provided. In an embodiment, the package substrate 500 may be one of various substrates (e.g., a printed circuit board (PCB), a flexible substrate, and a tape substrate). The package substrate 500 may be an interconnection substrate including interconnection insulating layers 510 and interconnection patterns 520, but the inventive concept is not limited to this example. The interconnection patterns 520 may be disposed in the interconnection insulating layers 510, and the lowermost interconnection pattern 520a may penetrate a portion of the interconnection insulating layer 510 and may protrude to a region under a bottom surface of the lowermost one of the interconnection insulating layers 510.

Outer coupling terminals 600 may be additionally disposed on a bottom surface of the package substrate 500. The outer coupling terminals 600 may be connected to the lowermost ones of the interconnection patterns 520. In an embodiment, the outer coupling terminals 600 may be formed of or include at least one of tin (Sn), bismuth (Bi), lead (Pb), silver (Ag), or alloys thereof. The outer coupling terminals 600 may be provided in the form of solder balls.

A plurality of semiconductor chips 10A may be stacked on the package substrate 500. Each of the semiconductor chips 10A may be substantially the same as the semiconductor device 10A described with reference to FIG. 2B. That is, each of the semiconductor chips 10A may include the input/output pads IOPAD formed on a side surface thereof. In the present specification, for convenience in description, a side surface of the semiconductor chip 10A, on which the input/output pads IOPAD are provided, may be referred to as a first side surface. That is, the first side surface may mean a side surface of the cell array structure CS and a side surface of the peripheral circuit structure PS, on which the input/output pad IOPAD described with reference to FIG. 2B is disposed.

The semiconductor chips 10A may be vertically stacked in such a way that the first side surfaces thereof are aligned to each other. For example, the semiconductor chips 10A may be vertically stacked in a state where the first side surfaces thereof are oriented in the same direction.

A conductive film 700 may be disposed on the first side surfaces of the semiconductor chips 10A. The conductive film 700 may cover at least a portion of the first side surfaces of the semiconductor chips 10A and may cover a portion of a top surface of the package substrate 500. The conductive film 700 may be in contact with the interconnection patterns 520 and the input/output pads IOPAD of the semiconductor chips 10A and may electrically connect them to each other. In other words, the interconnection patterns 520 and the input/output pads IOPAD may be electrically connected to each other by the conductive film 700.

In an embodiment, the conductive film 700 may include a conductive polymer material. For example, the conductive polymer material may include at least one of metallic materials and carbon-based materials (e.g., graphene and carbon nanotube), but the inventive concept is not limited to this example.

A mold layer MD may be disposed on the package substrate 500 to cover the semiconductor chips 10A. The mold layer MD may be provided to cover the semiconductor chips 10A, the conductive film 700, and the top surface of the package substrate 500. In an embodiment, the mold layer MD may include an epoxy molding compound or an adhesive material.

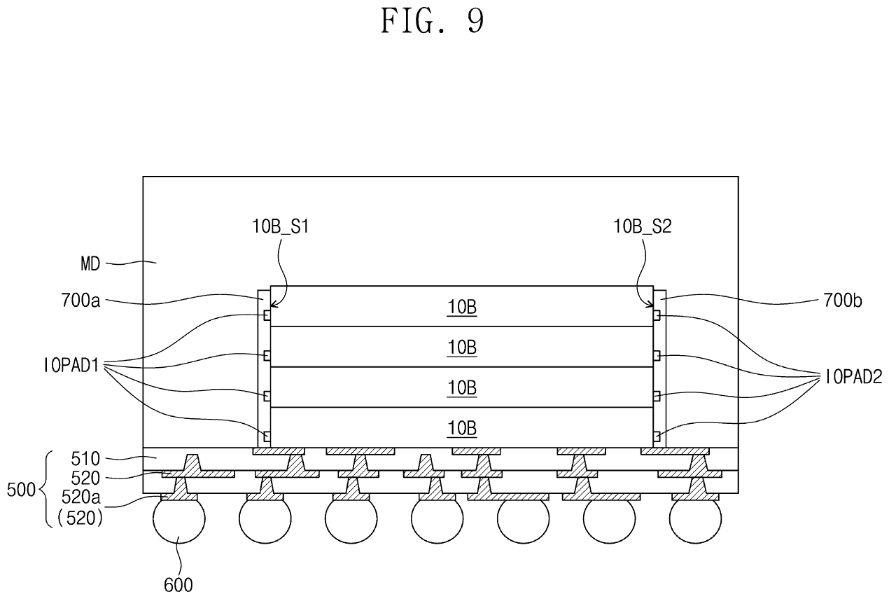

FIG. 9 is a sectional view illustrating a semiconductor package according to an example embodiment of the inventive concept. In the following description, a previously described element may be identified by the same reference number without repeating an overlapping description thereof, for the sake of brevity.

Referring to FIG. 9, a plurality of semiconductor chips 10B may be disposed on the package substrate 500. Each of the semiconductor chips 10B may be substantially the same as the semiconductor device 10B described with reference to FIGS. 3A and 3B. In other words, each of the semiconductor chips 10B may include the first and second input/output pads IOPAD1 and IOPAD2 which are formed on the side surfaces thereof. In the present specification, for convenience in description, a side surface of the semiconductor chip 10B provided with the first input/output pads IOPAD1 and IOPAD2 may be referred to as a first side surface 10B_S1, and a side surface of the semiconductor chip 10B provided with the second input/output pads IOPAD2 may be referred to as a second side surface 10B_S2. That is, the first side surface 10B_S1 may mean the side surface of the first cell array structure CS1 and the first side surface of the peripheral circuit structure PS, on which the first input/output pad IOPAD1 described with reference to FIGS. 3A and 3B is disposed, and the second side surface 10B_S2 may mean the side surface of the second cell array structure CS2 and the second side surface of the peripheral circuit structure PS, on which the second input/output pad IOPAD2 described with reference to FIGS. 3A and 3B is disposed.

The semiconductor chips 10B may be vertically stacked in such a way that the first and second side surfaces 10B_S1 and 10B_S2 thereof are aligned to each other. For example, the semiconductor chips 10B may be vertically stacked in a state where the first side surfaces 10B_S1 are oriented in the same direction and the second side surfaces 10B_S2 are oriented in the same direction. In an embodiment, the first side surfaces 10B_S1 and the second side surfaces 10B_S2 may be opposite to each other, but the inventive concept is not limited to this example. For example, when viewed in a plan view, the semiconductor chips 10B may have a rectangular shape, and each of the first and second side surfaces 10B_S1 and 10B_S2 may be one of the side surfaces of the semiconductor chips 10B.

A first conductive film 700 a may be disposed on the first side surfaces 10B_S1 of the semiconductor chips 10B. The first conductive film 700a may cover at least a portion of the first side surfaces 10B_S1 of the semiconductor chips 10B and may cover a portion of the top surface of the package substrate 500. The first conductive film 700a may be in contact with the interconnection patterns 520 and the first input/output pads IOPAD1 of the semiconductor chips 10B and may electrically connect them to each other.

A second conductive film 700b may be disposed on the second side surfaces 10B_S2 of the semiconductor chips 10B. The second conductive film 700b may cover at least a portion of the second side surfaces 10B_S2 of the semiconductor chips 10B and may cover a portion of the top surface of the package substrate 500. The second conductive film 700b may be in contact with the interconnection patterns 520 and the second input/output pads IOPAD2 of the semiconductor chips 10B and may electrically connect them to each other. In an embodiment, the first and second conductive films 700a and 700b may include a conductive polymer material.

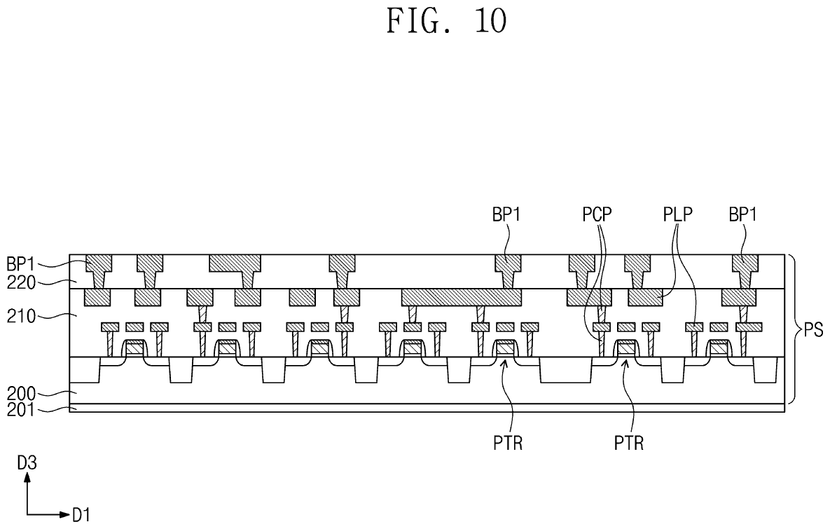

FIGS. 10 to 16 are sectional views illustrating a method of fabricating a semiconductor device, according to an example embodiment of the inventive concept, and corresponding to FIG. 3.

Referring to FIG. 10, the peripheral circuit structure PS, which includes the peripheral circuits PTR formed on the substrate 200, may be prepared.

In detail, the formation of the peripheral circuit structure PS may include forming a device isolation layer in the substrate 200 to define an active region, forming the peripheral circuits PTR on the active region of the substrate 200, forming the peripheral contact plugs PCP, the peripheral circuit lines PLP, the first bonding pads BP1 electrically connected to the peripheral circuits PTR, and forming a surface insulating layer 201 on a bottom or rear surface of the substrate 200.

The substrate 200 may be, for example, a silicon substrate, a silicon-germanium substrate, a germanium substrate, or a single-crystalline epitaxial layer grown from a single-crystalline silicon substrate.

The row and column decoders, the page buffers, and the control circuits serving as the peripheral circuits PTR may be formed on the substrate 200. Here, the peripheral circuits PTR may include MOS transistors using the substrate 200 as channel regions.

The first and second peripheral interlayer insulating layers 210 and 220 may include a single insulating layer or a plurality of vertically-stacked insulating layers covering the peripheral circuits PTR. In an embodiment, the first and second peripheral interlayer insulating layers 210 and 220 may include a plurality of lower insulating layers and etch stop layers between the lower insulating layers. Each of the first and second peripheral interlayer insulating layers 210 and 220 may include a silicon oxide layer, a silicon nitride layer, a silicon oxynitride layer, and/or a low-k dielectric layer.

The peripheral contact plugs PCP may be formed to penetrate portions of the first peripheral interlayer insulating layer 210 and may be connected to the peripheral circuits. The peripheral circuit lines PLP may be formed by depositing and patterning a conductive layer.

The first bonding pads BP1 may be formed in the second peripheral interlayer insulating layer 220. The first bonding pads BP1 may be electrically connected to the peripheral circuits PTR through the peripheral contact plugs PCP and the peripheral circuit lines PLP.

The first bonding pads BP1 may be formed using a damascene process. The top surfaces of the first bonding pads BP1 may be substantially coplanar with the top surface of the second peripheral interlayer insulating layer 220. In the following description, the expression of “two elements are coplanar with each other” may mean that a planarization process is performed on the elements. For example, the planarization process may be performed through a chemical mechanical polishing (CMP) process or an etch-back process.

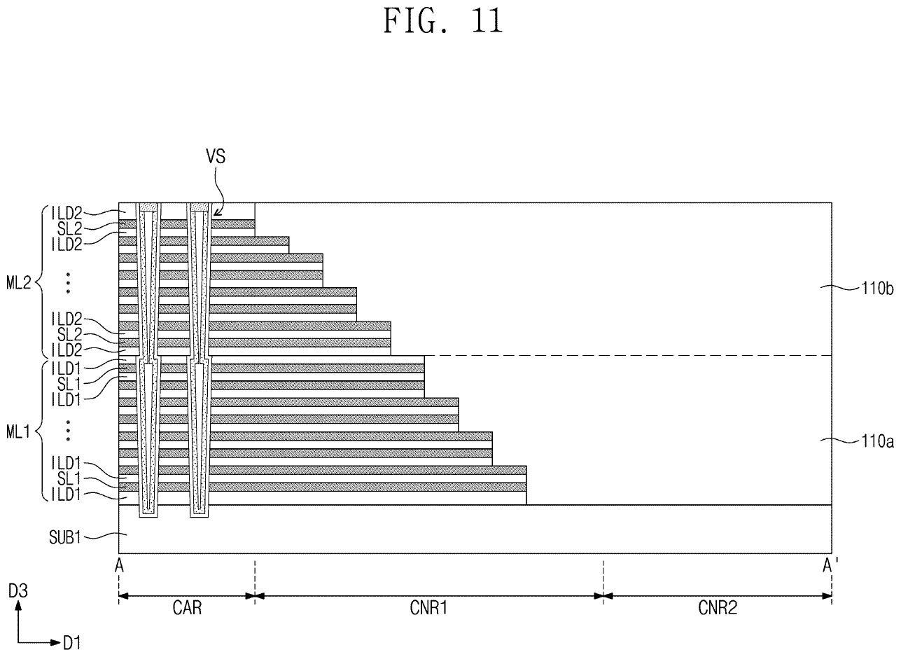

Referring to FIG. 11, a first mold structure ML1 may be formed on a sub-substrate SUB1.

The formation of the first mold structure ML1 may include forming a first layered structure (not shown), in which first insulating patterns ILD1 and first sacrificial layers SL1 are vertically and alternately stacked, and repeating a patterning process on the first layered structure. Thus, the first mold structure ML1 may have a stepwise structure in the first connection region CNR1.

The first insulating patterns ILD1 and the first sacrificial layers SL1 may be deposited using a thermal chemical vapor deposition (Thermal CVD) method, a plasma-enhanced chemical vapor deposition (PE-CVD) method, a physical chemical vapor deposition (physical CVD) method, or an atomic layer deposition (ALD) method.

In the first mold structure ML1, the first sacrificial layers SL1 may be formed of a material that can be etched with an etch selectivity with respect to the first insulating patterns ILD1. In an embodiment, the first sacrificial layers SL1 may be formed of an insulating material different from the first insulating patterns ILD1. For example, the first sacrificial layers SL1 may be formed of silicon nitride, and the first insulating patterns ILD1 may be formed of silicon oxide.

After the formation of the first mold structure ML1, the first planarization insulating layer 110a may be formed to cover the staircase structure of the first mold structure ML1.

Next, a second mold structure ML2 may be formed on the first mold structure ML1. In an embodiment, vertical sacrificial patterns (not shown) may be formed to penetrate the first mold structure ML1, before the formation of the second mold structure ML2.

The formation of the second mold structure ML2 may be substantially the same as the formation of the first mold structure ML1 described above. That is, the formation of the second mold structure ML2 may include forming a second layered structure (not shown), in which the second insulating patterns ILD2 and the second sacrificial layers SL2 are vertically and alternately stacked, on the first mold structure ML1 and repeating a patterning process on the second layered structure. Thus, the second mold structure ML2 may have a stepwise structure, in the first connection region CNR1.

The second sacrificial layers SL2 may be formed of the same material as the first sacrificial layers SL1 and may have substantially the same thickness as the first sacrificial layers SL1. The second sacrificial layers SL2 may be formed of an insulating material different from the second insulating patterns ILD2. The second sacrificial layers SL2 may be formed of the same material as the first sacrificial layers SL1. For example, the second sacrificial layers SL2 may be formed of or include silicon nitride, and the second insulating patterns ILD2 may be formed of or include silicon oxide.

After the formation of the second mold structure ML2, the second planarization insulating layer 110b may be formed to cover the staircase structure of the second mold structure ML2.

Next, vertical channel holes may be formed to penetrate the first and second mold structures ML1 and ML2 and to expose the sub-substrate SUB1. In the case where vertical sacrificial patterns (not shown) are formed in the first mold structure ML1, the formation of the vertical channel holes may include removing the vertical sacrificial patterns to expose the sub-substrate SUB1.

When the vertical channel holes are formed, dummy channel holes may be formed in the first connection region CNR1 to penetrate the planarization insulating layers 110a and 110b and portions of the first and second mold structures ML1 and ML2.

The formation of the vertical channel holes may include forming a hard mask pattern on the second mold structure ML2 and anisotropically etching the first and second mold structures ML1 and ML2 using the hard mask pattern as an etch mask. In the anisotropic etching process of forming the vertical channel holes, a top surface of the sub-substrate SUB1 may be over-etched, and thus, the top surface of the sub-substrate SUB1, which is exposed through the vertical channel holes, may be recessed to a specific depth. Furthermore, the recess depths of the sub-substrate SUB1 may vary depending on positions of the vertical channel holes in the anisotropic etching process of forming the vertical channel holes.

Next, the vertical structures VS may be formed in the vertical channel holes of the cell array region CAR. The formation of the vertical structures VS may include sequentially depositing a data storing layer and a vertical channel layer in the vertical channel hole and etching and planarizing the data storing layer and the vertical channel layer.

The data storing layer may be conformally deposited on bottom and side surfaces of the vertical channel hole by a chemical vapor deposition (CVD) method or an atomic layer deposition (ALD) method. The data storage layer may include a blocking insulating layer, a charge storing layer, and a tunnelling insulating layer, which are sequentially stacked in the vertical channel hole. The vertical channel layer may be conformally deposited on the data storage layer using a chemical vapor deposition (CVD) method or an atomic layer deposition (ALD) method. After the formation of the data storage layer and the vertical channel layer, the vertical channel holes may be filled with a gapfill insulating layer. Accordingly, as described above, the data storage pattern, the vertical channel pattern, and the vertical insulating pattern may be formed in each vertical channel hole.

Thereafter, the bit line conductive pads may be formed on top ends of the vertical channel patterns. The bit line conductive pads may be an impurity-doped region or may be formed of or include at least one of conductive materials. The bit line conductive pads may have top surfaces that are coplanar with a top surface of the uppermost one of the second insulating patterns ILD2.

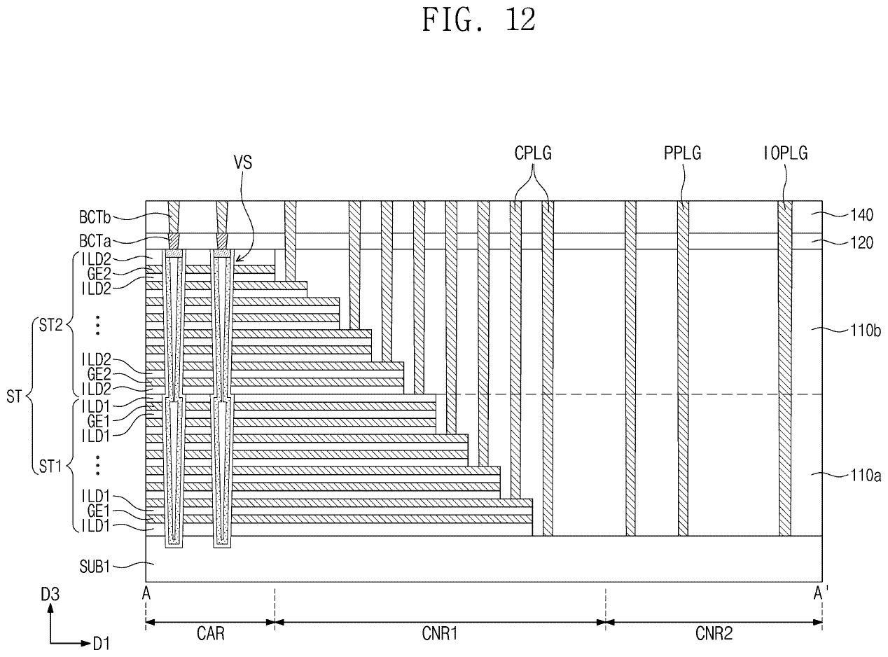

Referring to FIG. 12, the first interlayer insulating layer 120 may be formed on the planarization insulating layer 110b to cover top surfaces of first and second vertical structures VS1 and VS2.

Next, a replacement process may be performed to replace the first and second sacrificial layers SL1 and SL2 of the first and second mold structures ML1 and ML2 with the first and second gate patterns GE1 and GE2. As a result, the stack ST may be formed on the sub-substrate SUB1.

The replacement process may include isotropically etching the first and second sacrificial layers SL1 and SL2 using an etch recipe having an etch selectivity with respect to the first and second insulating patterns ILD1 and ILD2, the vertical structures VS, and the sub-substrate SUB1.

After the formation of the stack ST, the first bit line contact plugs BCTa, which are electrically connected to the bit line conductive pads, may be formed in the first interlayer insulating layer 120.

The second interlayer insulating layer 140 may be formed on the first interlayer insulating layer 120, and the cell contact plugs CPLG, which are connected to the stack ST, the peripheral contact plugs PPLG, and the input/output contact plug IOPLG, may be formed to penetrate the second interlayer insulating layer 140.

The peripheral contact plugs PPLG and the input/output contact plug IOPLG may be formed by forming a contact hole in the second connection region CNR2 to penetrate the first interlayer insulating layers 120 and the planarization insulating layers 110a and 110b and to expose the sub-substrate SUB1 and filling the contact hole with a conductive material.

Next, the second bit line contact plugs BCTb may be formed to penetrate the second interlayer insulating layer 140 and to be coupled to the first bit line contact plugs BCTa.

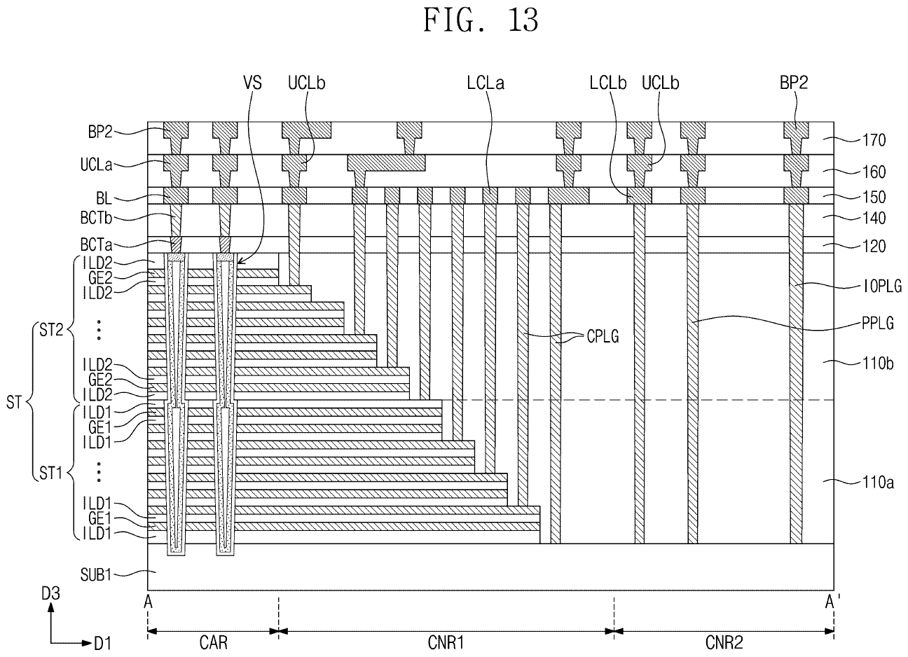

Referring to FIG. 13, the bit lines BL may be formed on the second interlayer insulating layer 140. The bit lines BL may be connected to the second bit line contact plugs BCTb.

The first and second lower conductive lines LCLa and LCLb, which are connected to the cell contact plugs CPLG, may be formed in the first and second connection regions CNR1 and CNR2.

Next, the third, fourth, and fifth interlayer insulating layers 150, 160, and 170 may be stacked on the second interlayer insulating layer 140, and the first upper conductive lines UCLa may be formed in the fourth interlayer insulating layer 160. The first upper conductive lines UCLa may be connected to the bit lines BL. At the same time, the second upper conductive lines UCLb may be formed in the first and second connection regions CNR1 and CNR2 and may be connected to the first and second lower conductive lines LCLa and LCLb.

The second bonding pads BP2 may be formed in the fifth interlayer insulating layer 170, and the second bonding pads BP2 may be connected to the first and second upper conductive lines UCLa and UCLb.

The first and second upper conductive lines UCLa and UCLb and the second bonding pads BP2 may be formed using a damascene process. The top surfaces of the second bonding pads BP2 may be substantially coplanar with a top surface of the fifth interlayer insulating layer 170.

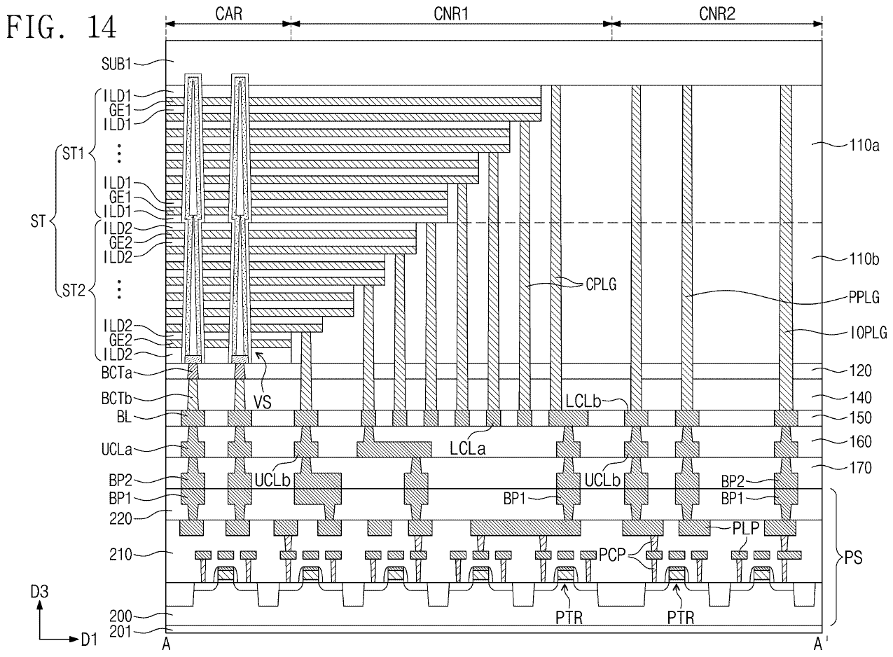

Referring to FIG. 14, a preliminary cell array structure formed on the sub-substrate SUB1 may be bonded to the peripheral circuit structure PS described with reference to FIG. 10. The first bonding pads BP1 of the peripheral circuit structure PS may be bonded to the second bonding pads BP2 of the cell array structure CS, and the fifth interlayer insulating layer 170 on the sub-substrate SUB1 may be bonded to the second peripheral interlayer insulating layer 220 on the substrate 200.

After the bonding of the first and second bonding pads BP1 and BP2, the cell array structure CS may be inverted. For example, the sub-substrate SUB1 of the preliminary cell array structure may be placed at the uppermost level, and the staircase structure of the stack ST may be placed in an inverted shape.

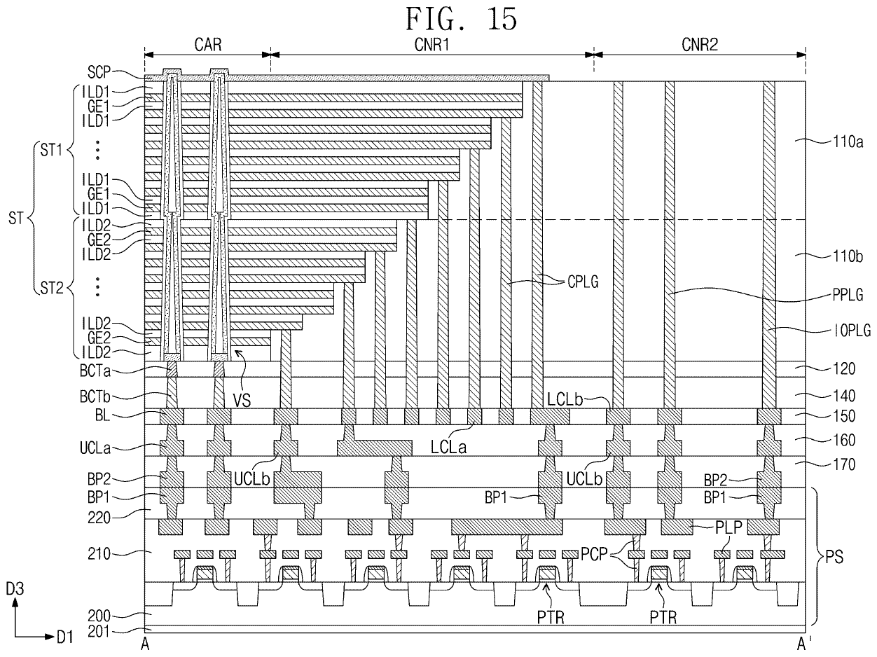

Referring to FIG. 15, the sub-substrate SUB1 may be removed. The removal of the sub-substrate SUB1 may include a grinding process, a planarization process, a dry etching process, and a wet etching process. As a result of the removal of the sub-substrate SUB1, the top surface of the first insulating patterns ILD1 of the stack ST and the top surface of the first planarization insulating layer 110a may be exposed to the outside. In addition, since the sub-substrate SUB1 is removed, the data storing layer of the vertical structure VS may protrude to a region on the uppermost one of the first insulating patterns ILD1. At the same time, the peripheral contact plugs PPLG and the input/output contact plug IOPLG may be exposed.

An upper portion of the data storing layer, which protrudes to a region on the first insulating pattern ILD1, may be removed to expose a top surface of the vertical channel layer. When the sub-substrate SUB1 is removed, the uppermost one of the first insulating patterns ILD1 may be used as an etch stop layer.

Next, an isotropic etching process may be performed on an upper portion of the data storing layer, which protrudes to a region on a top surface of the first insulating pattern ILD1. Thus, an upper portion of the vertical channel layer may be exposed, and the data storage pattern may be formed to have a pipe shape with open top and bottom ends.

An etch recipe having an etch selectivity with respect to the vertical channel layer may be used in the isotropic etching process on the data storing layer. The etching process on the data storing layer may include sequentially and isotropically etching the blocking insulating layer, the charge storing layer, and the tunnel insulating layer.

In detail, the isotropic etching process may include sequentially performing a first etching process of etching a portion of the blocking insulating layer, a second etching process of etching a portion of the charge storing layer, and a third etching process of etching a portion of the tunnel insulating layer. Here, an etching solution, which contains hydrofluoric acid or sulfuric acid, may be used in the first and third etching processes, and an etching solution, which contains phosphoric acid, may be used in the second etching process. The top surface of the data storage pattern may have a varying profile, depending on the etch recipes in the first, second, and third etching processes.

A semiconductor layer may be deposited on the uppermost one of the first insulating patterns ILD1. The semiconductor layer may be doped with impurities of a first conductivity type (e.g., an n-type), during the deposition of the semiconductor layer. The semiconductor layer may be formed by depositing an amorphous or poly silicon layer and performing a laser annealing process or a thermal treatment process thereon. The semiconductor layer may be patterned to form the source conductive pattern SCP on the cell array region CAR.

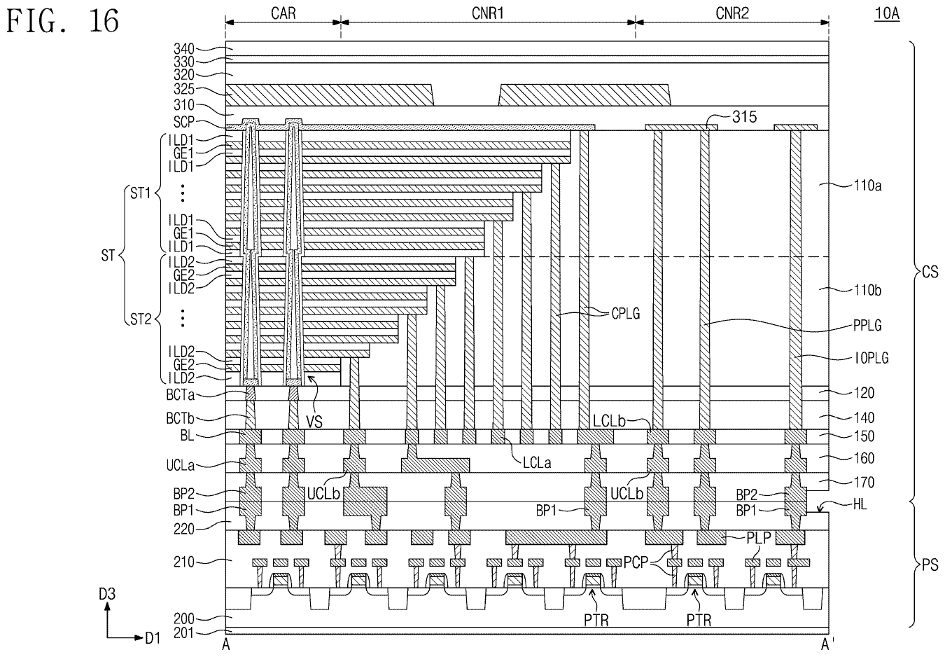

Referring to FIG. 16, the first upper insulating layer 310 may be formed to cover the source conductive pattern SCP, and the upper conductive patterns 315 may be formed on the first and second connection regions CNR1 and CNR2. The second upper insulating layer 320 and the second upper conductive patterns 325 may be formed on the first upper insulating layer 310. In an embodiment, each of the first and second upper insulating layers 310 and 320 may include a silicon oxide layer, a silicon nitride layer, or a silicon oxynitride layer.

Next, the capping insulating layer 330 and the passivation layer 340 may be sequentially formed. The capping insulating layer 330 may be, for example, a silicon nitride layer or a silicon oxynitride layer. The passivation layer 340 may be formed of or include at least one of polyimide-based materials (e.g., photo sensitive polyimide (PSPI)). The passivation layer 340 may be formed on the capping insulating layer 330 by a spin coating process.

Next, the cell array structure CS and the peripheral circuit structure PS may be diced to form a plurality of semiconductor chips that are separated from each other. Thus, side surfaces of each of the semiconductor chips (e.g., a side surface of the second connection region CNR2) may be exposed to the outside.

Contact holes HL may be formed in an exposed end portion of the second connection region CNR2. The first and second bonding pads BP1 and BP2, which are adjacent to each other in the end portion of the second connection region CNR2, may have side surfaces that are exposed through the contact hole HL. In an embodiment, the formation of the contact hole HL may be performed through a drilling process. As an example, the drilling process may include at least one of a laser drilling process, a mechanical drilling process, or a chemical etching process.

Referring back to FIGS. 3 and 16, the conductive contact 400 may be formed to fill the contact holes HL. The conductive contact 400 may be formed by filling the contact holes HL with a conductive material. Next, the input/output pad IOPAD may be formed to be connected to the conductive contact 400. The input/output pad IOPAD may be formed on side surfaces of the cell array structure CS and the peripheral circuit structure PS. In detail, the input/output pad IOPAD may be formed on side surfaces of the fifth interlayer insulating layer 170, the second peripheral interlayer insulating layer 220, and the conductive contact 400.

According to an embodiment of the inventive concept, a semiconductor device may include input/output pads, which are disposed on side surfaces of a cell array structure and a peripheral circuit structure and are electrically connected to each other through a conductive film. Since the input/output pads are formed on the side surfaces, a plurality of semiconductor chips may be stacked to have side surfaces, which are aligned to each other, without offset. Accordingly, it may be possible to reduce the size of a chip stack, in which a plurality of semiconductor chips are stacked, and to increase an integration density of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a package substrate;
a plurality of semiconductor chips stacked on the package substrate, each of the semiconductor chips having a first side surface; and
a first conductive film, which is electrically connected to the package substrate and is extended to a region on the first side surfaces of the semiconductor chips,
wherein each of the semiconductor chips comprises:
a peripheral circuit structure including first bonding pads on a first surface of a substrate;
a first cell array structure including a first stack and second bonding pads bonded to the first bonding pads; and
a first input/output pad disposed on the first side surface and electrically connected to the first conductive film.

2. The semiconductor device of claim 1,
wherein each of the semiconductor chips further comprises a conductive contact between the first and second bonding pads and the first input/output pad, and
wherein the first input/output pad is electrically connected to the conductive contact and the first and second bonding pads.

3. The semiconductor device of claim 2, wherein the conductive contact is in contact with side surfaces of the first and second bonding pads.

4. The semiconductor device of claim 1,
wherein the peripheral circuit structure comprises a peripheral interlayer insulating layer enclosing the first bonding pads,
wherein the first cell array structure comprises an interlayer insulating layer enclosing the second bonding pads, and
wherein the first input/output pad is disposed on side surfaces of the peripheral interlayer insulating layer and the interlayer insulating layer.

5. The semiconductor device of claim 1, wherein the first side surfaces of the semiconductor chips are aligned to each other.

6. The semiconductor device of claim 1, wherein each of the semiconductor chips further comprises second input/output pads, which are disposed on second side surfaces thereof.

7. The semiconductor device of claim 6, wherein the first side surface is opposite to the second side surface.

8. The semiconductor device of claim 1, wherein each of the semiconductor chips further comprises:
vertical structures penetrating the first stack; and
bit lines, which are disposed between the second bonding pads and the first stack in a vertical section and are connected to the vertical structures.

9. A semiconductor device, comprising:
a package substrate;
a plurality of semiconductor chips stacked on the package substrate, each of the semiconductor chips having a first side surface;
a mold layer provided on the package substrate to enclose the semiconductor chips; and
a first conductive film electrically connected to the package substrate and extended to a region on the first side surfaces of the semiconductor chips,
wherein each of the semiconductor chips comprises:
a peripheral circuit structure including first bonding pads on a first surface of a substrate and second bonding pads on a second surface opposite to the first surface;
a first cell array structure including third bonding pads bonded to the first bonding pads; and
a first input/output pad, which is disposed on the first side surface and is electrically connected to the first conductive film,
wherein the first cell array structure comprises:
a first stack including first insulating patterns and first gate patterns, which are vertically and alternately stacked;
vertical structures penetrating the first stack; and
bit lines electrically connected to the vertical structures.

10. The semiconductor device of claim 9,
wherein the peripheral circuit structure comprises a peripheral interlayer insulating layer enclosing the first bonding pads,
wherein the first cell array structure comprises an interlayer insulating layer enclosing the third bonding pads, and
wherein the first input/output pad is disposed on side surfaces of the peripheral interlayer insulating layer and the interlayer insulating layer.

11. The semiconductor device of claim 9, further comprising:
a second conductive film electrically connected to interconnection patterns and extended to a region on second side surfaces of the semiconductor chips,
wherein each of the semiconductor chips further comprises:
a second cell array structure including fourth bonding pads, which are bonded to the second bonding pads; and
a second input/output pad disposed on each of the second side surfaces and electrically connected to the second conductive film.

12. The semiconductor device of claim 11, wherein the first side surfaces of the semiconductor chips are aligned to each other, and wherein the second side surfaces of the semiconductor chips are aligned to each other.

13. The semiconductor device of claim 11,
wherein the first input/output pad is electrically connected to one of the third bonding pads adjacent to the first side surface, and
wherein the second input/output pad is electrically connected to one of the fourth bonding pads adjacent to the second side surface.

14. The semiconductor device of claim 11, wherein the first side surfaces are opposite to the second side surfaces.

15. A semiconductor device, comprising:
a peripheral circuit structure including first bonding pads on a first surface of a substrate and second bonding pads on a second surface of the substrate; and
a first cell array structure opposite to the first surface;
a second cell array structure opposite to the second surface;
a first input/output pad on a first side surface of the peripheral circuit structure; and
a second input/output pad on a second side surface of the peripheral circuit structure,
wherein the first cell array structure comprises:
a first stack including first insulating patterns and first gate patterns, which are vertically and alternately stacked;
first vertical structures penetrating the first stack; and
third bonding pads bonded to the first bonding pads, and
wherein the second cell array structure comprises:
a second stack including second insulating patterns and second gate patterns, which are vertically and alternately stacked;
second vertical structures penetrating the second stack; and
fourth bonding pads bonded to the second bonding pads.

16. The semiconductor device of claim 15,
wherein the first cell array structure comprises first bit lines between the first vertical structures and the third bonding pads, when viewed in a vertical cross-section, and
wherein the second cell array structure comprises second bit lines between the second vertical structures and the fourth bonding pads, when viewed in the vertical cross-section.

17. The semiconductor device of claim 15,
wherein the first input/output pad is in contact with a first side surface of the first cell array structure, and
wherein the second input/output pad is in contact with a second side surface of the second cell array structure.

18. The semiconductor device of claim 17,
wherein the first input/output pad is electrically connected to one of the third bonding pads adjacent to the first side surface, and
wherein the second input/output pad is electrically connected to one of the fourth bonding pads adjacent to the second side surface.

19. The semiconductor device of claim 15,
wherein the peripheral circuit structure further comprises:
a first peripheral interlayer insulating layer enclosing the first bonding pads; and
a second peripheral interlayer insulating layer enclosing the second bonding pads,
wherein the first cell array structure further comprises a first interlayer insulating layer enclosing the third bonding pads,
wherein the second cell array structure further comprises a second interlayer insulating layer enclosing the fourth bonding pads,
wherein the first input/output pad is placed on side surfaces of the first peripheral interlayer insulating layer and the first interlayer insulating layer, and
wherein the second input/output pad is placed on side surfaces of the second peripheral interlayer insulating layer and the second interlayer insulating layer.

20. The semiconductor device of claim 15, wherein the peripheral circuit structure further comprises:
peripheral circuits on the first surface of the substrate; and
a penetration via pattern, which is provided to penetrate the substrate and is electrically connected to a portion of the peripheral circuits.
